(19) United States
(12) Patent Application Publication
(10) Pub. No.: US 2024/0279549 A1
(43) Pub. Date: Aug. 22, 2024

(54) ETCHING COMPOSITIONS

(71) Applicant: Fujifilm Electronic Materials U.S.A., Inc., N. Kingstown, RI (US)

(72) Inventors: Kohei Hayashi, Gilbert, AZ (US); Thomas Dory, Gilbert, AZ (US); William A. Wojtczak, Mesa, AZ (US)

(21) Appl. No.: 18/436,073

(22) Filed: Feb. 8, 2024

Related U.S. Application Data
(60) Provisional application No. 63/444,600, filed on Feb. 10, 2023.

(51) Int. Cl. C09K 13/08; H01L 21/3105

(52) U.S. Cl. CPC C09K 13/08; H01L 21/31056

(57) ABSTRACT

The present disclosure is directed to etching compositions that are useful for, e.g., selectively removing silicon nitride from a semiconductor substrate as an intermediate step in a multistep semiconductor manufacturing process.

### CROSS-REFERENCE TO RELATED APPLICATION

The present application claims priority to U.S. Provisional Application Ser. No. 63/444,600, filed on Feb. 10, 2023, the contents of which are hereby incorporated by reference in their entirety

### FIELD OF THE DISCLOSURE

The present disclosure relates to etching compositions and processes of using etching compositions. In particular, the present disclosure relates to etching compositions that can selectively etch silicon nitride in the presence of other exposed or underlying materials, such as metal conductors (e.g., copper), gate materials (e.g., SiGe), barrier materials, insulator materials (e.g., low-k dielectric materials).

### BACKGROUND OF THE DISCLOSURE

The semiconductor industry is rapidly decreasing the dimensions and increasing the density of electronic circuitry and electronic components in microelectronic devices, silicon chips, memory chips, liquid crystal displays, MEMS (Micro Electro Mechanical Systems), printed wiring boards, and the like. The integrated circuits within them are being layered or stacked with insulating layers having constantly decreasing thicknesses between each circuitry layer. As the feature sizes have shrunk, patterns have become smaller, and device performance parameters tighter and more robust. As a result, various issues which heretofore could be tolerated can no longer be tolerated or have become more of an issue due to the smaller feature size.

In the production of advanced integrated circuits, to minimize problems associated with the higher density and to optimize performance, both high k and low k insulators, and assorted barrier layer materials have been employed.

Silicon nitride (SiN) can be utilized in the manufacturing of semiconductor devices, liquid crystal displays, MEMS (Micro Electro Mechanical Systems), printed wiring boards and the like. Silicon nitride frequently needs to be removed in the presence of other exposed or underlying materials in a semiconductor substrate during an etching process.

### SUMMARY OF THE DISCLOSURE

In the construction of semiconductor devices, silicon nitride (SiN) frequently needs to be etched. In the various types of uses and device environment of SiN, other layers are in contact with or otherwise exposed at the same time as this material is etched. Highly selective etching of the SiN in the presence of these other materials (e.g., metal conductors, dielectrics, channel materials, gate materials, and hard masks) is typically needed for device yield and long life.

The present disclosure relates to compositions and processes for selectively etching SiN relative to hard mask layers, gate materials (e.g., SiGe, or SiOx) and/or low-k dielectric layers (e.g., SiOx, carbon doped oxide, SiCO, or silicon oxycarbonitride (SiOCN)) that are present in the semiconductor device using an etching composition containing a high concentration of phosphoric acid at an elevated temperature (e.g., 110° C. to 160° C.). More specifically, the present disclosure relates to compositions and processes for selectively etching SiN relative to SiOx and/or SiOCN.

In one aspect, this disclosure features an etching composition that includes (1) phosphoric acid; (2) at least one fluorine-containing inorganic acid or a salt thereof; (3) at least one nitrogen-containing compound that includes an alkoxysilane group; (4) at least one silane compound different from the at least one nitrogen-containing compound, in which the at least one silane compound includes a —Si—N— group, a halo group, an aminoalkyl group, an alkoxyl group, or a combination thereof; and (5) water.

In another aspect, this disclosure features a method that includes contacting a semiconductor substrate containing a SiN film (e.g., in a SiN-containing feature) with an etching composition described herein to substantially remove the SiN film.

In still another aspect, this disclosure features an article formed by the method described above, in which the article is a semiconductor device (e.g., an integrated circuit).

### DETAILED DESCRIPTION OF THE DISCLOSURE

As defined herein, unless otherwise noted, all percentages expressed should be understood to be percentages by weight to the total weight of the composition. Unless otherwise noted, ambient temperature is defined to be between about 16 and about 27 degrees Celsius (° C.). As used herein, the terms “layer” and “film” are used interchangeably.

In general, the disclosure features an etching composition (e.g., an etching composition for selectively removing SiN) that includes (e.g., comprises or consists of) phosphoric acid; at least one fluorine-containing inorganic acid or a salt thereof; at least one nitrogen-containing compound (e.g., one including an alkoxysilane group); at least one silane compound (e.g., one including a —Si—N— group, a halo group, an aminoalkyl group, an alkoxyl group, or a combination thereof) different from the at least one nitrogen-containing compound; and water. In some embodiments, the etching composition contains these five types of components only.

In some embodiments, the phosphoric acid can be added into an etching composition described herein in the form of a concentrated phosphoric acid aqueous solution (e.g., containing at least 80 wt % phosphoric acid). Without wishing to be bound by theory, it is believed that the phosphoric acid can facilitate the removal of SiN on a semiconductor substrate during the etching process and enhance the SiN etch selectivity.

In some embodiments, the phosphoric acid contained in an etching composition described herein can be in an amount that, in combination with the other materials of the etching composition, provides desired etching performance (e.g., desired silicon nitride etch rate and selectivity). In some embodiments, the phosphoric acid is in an amount of at least about 60 wt % (e.g., at least about 62 wt %, at least about 64 wt %, at least about 65 wt %, at least about 66 wt %, at least about 68 wt %, at least about 70 wt %, at least about 72 wt %, at least about 74 wt %, at least about 75 wt %, at least about 76 wt %, at least about 78 wt %, or at least about 80 wt %) to at most about 85 wt % (e.g., at most about 84 wt %, at most about 82 wt %, at most about 80 wt %, at most about 78 wt %, at most about 76 wt %, at most about 75 wt %, at most about 74 wt %, at most about 72 wt %, or at most about 70 wt %) of an etching composition described herein.

In some embodiments, the etching composition of this disclosure can include at least one (e.g., two, three, or four) fluorine-containing inorganic acid or a salt thereof. The fluorine-containing inorganic acid described herein can be an inorganic acid containing an inorganic element such as silicon, phosphor, boron, titanium, or zirconium. The salt of the fluorine-containing inorganic acid can be an ammonium salt (e.g., a tetraalkylammonium salt). Examples of suitable fluorine-containing inorganic acids or salts thereof include hexafluorosilicic acid, methylpentafluorosilicic acid, ammonium hexafluorosilicate, hexafluorophosphoric acid, ammonium hexafluorophosphate, tetrafluoroboric acid, hexafluorotitanic acid, hexafluorozirconic acid, tetramethylammonium tetrafluoroborate, tetraethylammonium tetrafluoroborate, tetramethylammonium hexafluorophosphate, tetraethylammonium hexafluorophosphate, and tetrabutylammonium hexafluorophosphate. Without wishing to be bound by theory, it is believed that the fluorine-containing inorganic acid or a salt thereof can facilitate the removal of SiN and inhibit the removal of other dielectric materials (e.g., silicon oxide (SiOx) and silicon oxycarbonitride (SiOCN)) on a semiconductor substrate during the etching process, thereby enhancing the SiN etch selectivity (e.g., the SiN/SiOCN and/or SiN/SiOx etch selectivity).

In some embodiments, the at least one fluorine-containing inorganic acid or a salt thereof contained in an etching composition described herein can be in an amount that, in combination with the other materials of the etching composition, provides desired etching performance, including desired silicon nitride etch rate and selectivity. For example, the at least one fluorine-containing inorganic acid or a salt thereof can be in an amount of at least about 0.001 wt % (e.g., at least about 0.002 wt %, at least about 0.004 wt %, at least about 0.005 wt %, at least about 0.006 wt %, at least about 0.008 wt %, at least about 0.01 wt %, at least about 0.02 wt %, at least about 0.04 wt %, or at least about 0.05 wt %) to at most about 0.1 wt % (e.g., at most about 0.08 wt %, at most about 0.06 wt %, at most about 0.05 wt %, at most about 0.04 wt %, at most about 0.02 wt %, at most about 0.01 wt %, at most about 0.008 wt %, at most about 0.006 wt %, or at most about 0.005 wt %) of an etching composition described herein.

In some embodiments, the etching composition of this disclosure can include at least one (e.g., two, three, or four) nitrogen-containing compound. In some embodiments, the nitrogen-containing compound can include an alkoxysilane group, such as a C₁-C₆ alkoxysilane group. In some embodiments, the nitrogen-containing compound can include an alkoxysilane substituted polyethyleneimine (e.g., a monoalkoxysilane substituted polyethyleneimine, a dialkoxysilane substituted polyethyleneimine, or a trialkoxysilane substituted polyethyleneimine) or a salt thereof. In some embodiments, the alkoxysilane substituted polyethyleneimine is a polymer having a monomer repeat unit of formula (I):

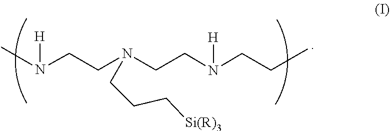

in which each R independently is a C₁-C₆ alkyl or C₁-C₆ alkoxy, and at least one (e.g., two or three) R is C₁-C₆ alkoxy. As used herein, examples of “C₁-C₆ alkyl” can include methyl, ethyl, propyl, isopropyl, butyl, isobutyl, t-butyl, pentyl, isopentyl, hexyl, and isohexyl. As used herein, examples of “C₁-C₆ alkoxy” can include methoxy, ethoxy, propoxy, isopropoxy, butoxy, isobutoxy, t-butoxy, pentoxy, isopentoxy, hexoxy, and isohexoxy. An example of the alkoxysilane substituted polyethyleneimine is trimethoxysilyl polyethyleneimine.

In some embodiments, the alkoxysilane substituted polyethyleneimine has an average molecular weight number of from at least about 500 g/mol (e.g., at least about 1000 g/mol, at least about 1500 g/mol, at least about 2000 g/mol, or at least about 2500 g/mol) to at most about 5000 g/mol (e.g., at most about 4500 g/mol, at most about 4000 g/mol, at most about 3500 g/mol, at most about 3000 g/mol, or at most about 2500 g/mol). Without wishing to be bound by theory, it is believed that an alkoxysilane substituted polyethyleneimine having an average molecular weight number in the above range can enhance the SiN etch selectivity (e.g., the SiN/SiOCN and/or SiN/SiOx etch selectivity). For example, without wishing to be bound by theory, it is believed that, if the average molecular weight number of an alkoxysilane substituted polyethyleneimine is lower than about 500 g/mol, the etching composition containing such a polyethyleneimine may not effectively inhibit the etch rate of SiOCN, thereby reducing the SiN/SiOCN etch selectivity. As another example, without wishing to be bound by theory, it is believed that, if the average molecular weight number of an alkoxysilane substituted polyethyleneimine is higher than about 5000 g/mol, the etching composition containing such a polyethyleneimine may inhibit the etch rate of SiN, thereby reducing the SiN/SiOCN etch selectivity.

In some embodiments, the at least one nitrogen-containing compound can include an alkoxysilane substituted trialkylamine compound or an alkoxysilane substituted tetraalkylammonium salt. In some embodiments, the alkoxysilane substituted tetraalkylammonium salt is a compound of formula (II):

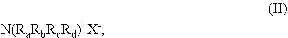

in which Rₐ is a C₁-C₆ alkyl substituted by Si(R′)₃, wherein each R′ independently is a C₁-C₆ alkyl or C₁-C₆ alkoxy and at least one R′ is C₁-C₆ alkoxy; each of R_{b}, R_{c}, and R_{d} independently is C₁-C₁₅ alkyl; and X is a halogen. An example of a compound of formula (II) is

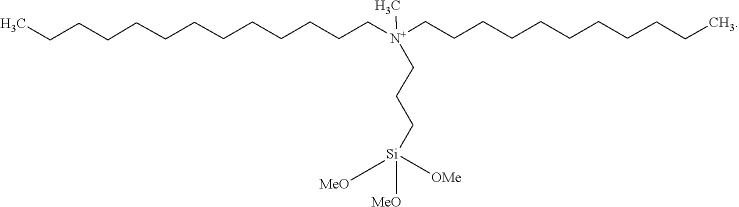 [SMILES: CCCCCCCCCCCCC[N+](C)(CCCCCCCCCCC)CCC[Si](OC)(OC)OC]

In some embodiments, the alkoxysilane substituted trialkylamine compound is a compound of formula (II′): N(RₐR_{b}R_{c}R_{d})⁺X⁻ (II′), in which Rₐ, R_{b}, R_{c}, and R_{d} are defined above.

Without wishing to be bound by theory, it is believed that the nitrogen-containing compound can inhibit the removal of dielectric materials other than SiN (e.g., silicon oxide (SiOx) and silicon oxycarbonitride (SiOCN)) on a semiconductor substrate during the etching process, thereby enhancing the SiN etch selectivity (e.g., the SiN/SiOCN and/or SiN/SiOx etch selectivity).

In some embodiments, the at least one nitrogen-containing compound contained in an etching composition described herein can be in an amount that, in combination with the other materials of the etching composition, provides desired etching performance, including desired silicon nitride etch selectivity. For example, the at least one nitrogen-containing compound can be in an amount of at least about 0.001 wt % (e.g., at least about 0.002 wt %, at least about 0.004 wt %, at least about 0.005 wt %, at least about 0.006 wt %, at least about 0.008 wt %, at least about 0.01 wt %, at least about 0.02 wt %, at least about 0.04 wt %, at least about 0.05 wt %, at least about 0.06 wt %, at least about 0.08 wt %, at least about 0.1 wt %, at least about 0.2 wt %, at least about 0.4 wt %, or at least about 0.5 wt %) to at most about 1 wt % (e.g., at most about 0.8 wt %, at most about 0.6 wt %, at most about 0.5 wt %, at most about 0.4 wt %, at most about 0.2 wt %, at most about 0.1 wt %, at most about 0.08 wt %, at most about 0.06 wt %, at most about 0.05 wt %, at most about 0.04 wt %, at most about 0.02 wt %, at most about 0.01 wt %, at most about 0.008 wt %, at most about 0.006 wt %, or at most about 0.005 wt %) of an etching composition described herein.

In some embodiments, the etching composition of this disclosure can include at least one (e.g., two, three, or four) silane compound. In some embodiments, the silane compound can be an azasilacyclopentane compound, an azasilane compound, or a trialkylsilane compound optionally containing at least one (e.g., two, three, or four) substituent (either on an alkyl group or the silicon atom) that includes a nitrogen atom, an oxygen atom, or a halogen atom (e.g., F, Cl, Br, or I). In some embodiments, the substituent can include a halo group, a C₁-C₆ alkoxy group, an ethylene oxide group, a C₁-C₆ alkyl group optionally substituted by an amino or C₁-C₆ alkylamino group, or a combination thereof. In some embodiments, each of the alkyl groups on the trialkylsilane compound independently can be further substituted by an amino group (i.e., NH₂) and/or a C₁-C₆ alkoxy group.

In some embodiments, the azasilacyclopentane compound is a compound of formula (III):

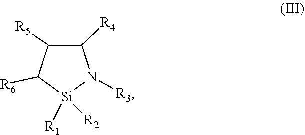

in which each of R₁-R₆, independently, is H or C₁-C₆ alkyl (e.g., methyl or ethyl) optionally substituted by at least one substituent (e.g., NH₂). In some embodiments, each of R₁, R₂, and R₅, independently can be H or CH₃. In some embodiments, R₃ is CH₃ or (CH₂)(CH₂)NH₂. Examples of the compounds of formula (III) can include

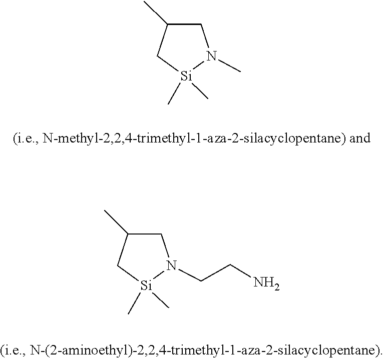

In some embodiments, the azasilane compound can be a linear or non-cyclic azasilane compound. In some embodiments, the azasilane compound can include at least one (e.g., two or three) —Si—N— bond. An example of an azasilane compound is

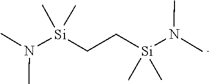

In some embodiments, the trialkylsilane compound can include an amino group, a halo group, a C₁-C₆ alkoxy group, an alkylamino group (e.g., an ethylamino group), an alkyl group (e.g., a C₁-C₁₀ alkyl group) optionally substituted by at least one amino group and/or containing at least one (e.g., two or three) nitrogen or oxygen atom in the middle of the alkyl chain, or a combination thereof. Examples of such trialkylsilane compounds include

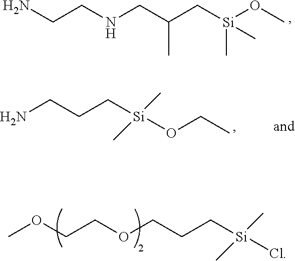

Without wishing to be bound by theory, it is believed that the silane compound can prevent or minimize oligomerization of the nitrogen-containing compound that includes an alkoxysilane group, thereby improving the consistency of the function of the nitrogen-containing compound (e.g., inhibition of the removal of dielectric materials) and the consistency of the etch rates of dielectric materials (e.g., SiN, SiOx, and SiOCN) on a semiconductor substrate during the etching process.

In some embodiments, the at least one silane compound contained in an etching composition described herein can be in an amount that, in combination with the other materials of the etching composition, provides desired etching performance, including desired silicon nitride etch rate and selectivity. For example, the at least one silane compound can be in an amount of at least about 0.01 wt % (e.g., at least about 0.02 wt %, at least about 0.04 wt %, at least about 0.05 wt %, at least about 0.06 wt %, at least about 0.08 wt %, at least about 0.1 wt %, at least about 0.2 wt %, at least about 0.4 wt %, at least about 0.5 wt %, at least about 0.6 wt %, at least about 0.8 wt %, at least about 1 wt %, or at least about 2 wt %) to at most about 5 wt % (e.g., at most about 4 wt %, at most about 3 wt %, at most about 2 wt %, at most about 1 wt %, at most about 0.8 wt %, at most about 0.6 wt %, at most about 0.5 wt %, at most about 0.4 wt %, at most about 0.2 wt %, or at most about 0.1 wt %) of an etching composition described herein.

In general, the etching composition of this disclosure can include water as a solvent. In some embodiments, the water can be de-ionized and ultra-pure, contain no organic contaminants, and/or have a minimum resistivity of about 4 to about 17 mega Ohms or at least about 17 mega Ohms. In some embodiments, the water is in an amount of from at least about 15 wt % (e.g., at least about 16 wt %, at least about 18 wt %, at least about 20 wt %, at least about 22 wt %, at least about 24 wt %, at least about 25 wt %, at least about 26 wt %, at least about 28 wt %, or at least about 30 wt %) to at most about 40 wt % (e.g., at most about 38 wt %, at most about 36 wt %, at most about 35 wt %, at most about 34 wt %, at most about 32 wt %, at most about 30 wt %, at most about 28 wt %, at most about 26 wt %, at most about 24 wt %, at most about 22 wt %, or at most about 20 wt %) of the etching composition. Without wishing to be bound by theory, it is believed that, if the amount of water is greater than 40 wt % of the composition, it would adversely impact the SiN etch rate, and reduce its removal during the etching process. On the other hand, without wishing to be bound by theory, it is believed that the etching composition of this disclosure should include a certain level of water (e.g., at least about 15 wt %) to avoid reduction in the etching performance.

The etching composition described herein can optionally include at least one (e.g., two, three, or four) oxidizing agent. Examples of suitable oxidizing agents include periodic acid, perchloric acid, and hydrogen peroxide.

In some embodiments, the at least one oxidizing agent can be from at least about 0.1 wt % (e.g., at least about 0.2 wt %, at least about 0.3 wt %, at least about 0.4 wt %, at least about 0.5 wt %, at least about 0.6 wt %, at least about 0.7 wt %, at least about 0.8 wt %, at least about 0.9 wt %, or at least about 1 wt %) to at most about 5 wt % (e.g., at most about 4.5 wt %, at most about 4 wt %, at most about 3.5 wt %, at most about 3 wt %, at most about 2.5 wt %, at most about 2 wt %, at most about 1.5 wt %, at most about 1 wt %, at most about 0.9 wt %, at most about 0.8 wt %, at most about 0.7 wt %, at most about 0.6 wt %, or at most about 0.5 wt %) of the etching composition of this disclosure. Without wishing to be bound by theory, it is believed that the oxidizing agent can facilitate and enhance the removal of SiN on a semiconductor substrate. In some embodiments, the etching composition of this disclosure can be substantially free of an oxidizing agent.

In some embodiments, the etching composition of this disclosure can optionally include at least one (e.g., two, three, or four) organic solvent. In some embodiments, the organic solvent can be a water soluble organic solvent. As defined herein, a “water soluble” substance (e.g., a water soluble organic solvent) refers to a substance having a solubility of at least 1% by weight in water at 25° C. In some embodiments, the organic solvent can be selected from the group consisting of water soluble alcohols (e.g., alkane diols or glycols such as alkylene glycols), water soluble ketones, water soluble esters, and water soluble ethers (e.g., glycol ethers). Examples of suitable organic solvents include glycerol, propylene glycol, hexylene glycol, 1,3-propanediol, ethylene glycol butyl ether, 3-methoxy-3-methyl-1-butanol, acetone, cyclohexanone, ethyl acetate, and propylene glycol monoethyl ether acetate.

In some embodiments, the at least one organic solvent can be from at least about 5 wt % (e.g., at least about 10 wt %, at least about 15 wt %, at least about 20 wt %, at least about 25 wt %, at least about 30 wt %, at least about 35 wt %, or at least about 40 wt %) to at most about 75 wt % (e.g., at most about 70 wt %, at most about 65 wt %, at most about 60 wt %, at most about 55 wt %, at most about 50 wt %, at most about 45 wt %, or at most about 40 wt %) of the etching composition. In some embodiments, the etching composition of this disclosure can be substantially free of an organic solvent.

In some embodiments, the etching composition of this disclosure can have a pH of at least about 0 (e.g., at least about 0.2, at least about 0.4, at least about 0.5, at least about 0.6, at least about 0.8, at least about 1, at least about 1.2, at least about 1.4, or at least about 1.5) and/or at most about 2 (e.g., at most about 1.8, at most about 1.6, at most about 1.5, at most about 1.4, at most about 1.2, at most about 1, at most about 0.8, at most about 0.6, or at most about 0.5). Without wishing to be bound by theory, it is believed that an etching composition having a pH lower than 0 would cause significant corrosion to other materials on a substrate. Further, without wishing to be bound by theory, it is believed that an etching composition having a pH higher than 2 would not have a sufficient SiN removal rate.

In some embodiments, the cleaning compositions of this disclosure can optionally include at least one (e.g., two, three, or four) pH adjusting agent (e.g., an acid or a base) to control the pH to from about 0 to about 2. The amount of the pH adjusting agent required, if any, can vary as the concentrations of the other components (e.g., the quaternary ammonium hydroxide and the acid) are varied in different formulations. In some embodiments, the pH adjusting agent can be at least about 0.1 wt % (e.g., at least about 0.2 wt %, at least about 0.4 wt %, at least about 0.5 wt %, at least about 0.6 wt %, at least about 0.8 wt %, at least about 1 wt %, at least about 1.2 wt %, at least about 1.4 wt %, or at least about 1.5 wt %) and/or at most about 3 wt % (e.g., at most about 2.8 wt %, at most about 2.6 wt %, at most about 2.5 wt %, at most about 2.4 wt %, at most about 2.2 wt %, at most about 2 wt %, or at most about 1.8 wt %) of the etching composition. In some embodiments, the etching composition of this disclosure can be substantially free of a pH adjusting agent.

In some embodiments, the pH adjusting agent is free of any metal ion (except for a trace amount of metal ion impurities). Suitable metal ion free pH adjusting agents include acids and bases. Suitable acids that can be used as a pH adjusting agent include organic acids (e.g., carboxylic acids) and inorganic acids. Exemplary carboxylic acids include, but are not limited to, monocarboxylic acids, bicarboxylic acids, tricarboxylic acids, α-hydroxyacids and β-hydroxyacids of monocarboxylic acids, α-hydroxyacids or β-hydroxyacids of bicarboxylic acids, or α-hydroxyacids and β-hydroxyacids of tricarboxylic acids. Examples of suitable carboxylic acids include citric acid, maleic acid, fumaric acid, lactic acid, glycolic acid, oxalic acid, tartaric acid, succinic acid, and benzoic acid. Examples of suitable inorganic acids include phosphoric acid, nitric acid, sulfuric acid, and hydrochloric acid.

Suitable bases that can be used as a pH adjusting agent include ammonium hydroxide, monoamines (including alkanolamines), and cyclic amines. Examples of suitable monoamines include, but are not limited to, triethylamine, tributylamine, tripentylamine, diethylamine, butylamine, dibutylamine, and benzylamine. Examples of suitable alkanolamines include, but are not limited to, monoethanolamine, diethanolamine, triethanolamine, and aminopropyldiethanolamine. Examples of suitable cyclic amines include, but are not limited to, 1,8-diazabicyclo[5.4.0]-7-undecene (DBU), 1,5-diazabicyclo[4.3.0]-5-nonene (DBN), and octahydro-2H-quinolizine.

In some embodiments, the etching composition of the present disclosure can contain additives such as pH adjusting agents, corrosion inhibitors, surfactants, additional organic solvents, biocides, and defoaming agents as optional components. Examples of certain suitable additives include alcohols (e.g., polyvinyl alcohol and sugar alcohols). Examples of suitable defoaming agents include polysiloxane defoamers (e.g., polydimethylsiloxane), polyethylene glycol methyl ether polymers, ethylene oxide/propylene oxide copolymers, and glycidyl ether capped acetylenic diol ethoxylates (such as those described in U.S. Pat. No. 6,717,019, herein incorporated by reference). Examples of suitable surfactants can be cationic, anionic, nonionic, and amphoteric surfactants.

In general, the etching composition of the present disclosure can have a relatively high SiN removal rate. In some embodiments, the etching composition can have a SiN removal rate of from at least about 10 Å/min (e.g., at least about 15 Å/min, at least about 20 Å/min, at least about 25 Å/min, at least about 30 Å/min, at least about 35 Å/min, or at least about 40 Å/min) to at most about 100 Å/min (e.g., at most about 90 Å/min, at most about 80 Å/min, at most about 70 Å/min, at most about 60 Å/min, or at most about 50 Å/min) when a SiN film is treated by the etching composition at 130° C. for one minute.

In general, the etching composition of the present disclosure can have a relatively low SiOCN removal rate. In some embodiments, the etching composition can have a SiOCN removal rate of from at most about 0.5 Å/min (e.g., at most about 0.45 Å/min, at most about 0.4 Å/min, at most about 0.35 Å/min, at most about 0.3 Å/min, at most about 0.25 Å/min, at most about 0.2 Å/min, at most about 0.15 Å/min, or at most about 0.1 Å/min) to 0 Å/min (e.g., at least 0.001 Å/min) when a SiOCN film is treated by the etching composition at 130° C. for 20 minutes.

In general, the etching composition of the present disclosure can have a relatively low SiOx removal rate. In some embodiments, the etching composition can have a SiOx removal rate of from at most about 5 Å/min (e.g., at most about 4.5 Å/min, at most about 4 Å/min, at most about 3.5 Å/min, at most about 3 Å/min, at most about 2.5 Å/min, at most about 2 Å/min, at most about 1.5 Å/min, or at most about 1 Å/min) to 0 Å/min (e.g., at least 0.01 Å/min) when a SiOx film is treated by the etching composition at 130° C. for 30 minute.

In general, the etching composition of the present disclosure can have a relatively high SiN/dielectric material (e.g., SiOx, or SiOCN) removal rate selectivity (i.e., a high ratio of SiN removal rate over dielectric material removal rate). In some embodiments, the etching composition can have a SiN/SiOx removal rate selectivity of at least about 10 (e.g., at least about 20, at least about 40, at least about 50, at least about 60, at least about 80, at least about 100, at least about 150, at least about 200, at least about 250, at least about 300, at least about 350, at least about 400, at least about 450, at least about 500, or at least about 1000) and/or at most about 5000 (e.g., at most about 4000, at most about 3000, at most about 2000, or at most about 1000) when the etch rates of SiN and SiOx are measured under the same conditions (e.g., at the same etching temperature). In some embodiments, the etching composition can have a SiN/SiOCN removal rate selectivity of at least about 100 (e.g., at least about 150, at least about 200, at least about 250, at least about 300, at least about 350, at least about 400, at least about 450, at least about 500, at least about 600, at least about 700, at least about 800, at least about 900, or at least about 1000) and/or at most about 5000 (e.g., at most about 4000, at most about 3000, at most about 2000, or at most about 1000) when the etch rates of SiN and SiOCN are measured under the same conditions (e.g., at the same etching temperature). In some embodiments, as the SiOx and SiOCN etch rates are significantly lower than the SiN etch rate, the etching times for SiOx and SiOCN are longer than the etching time for SiN to obtain reliable SiOx and SiOCN etch rates. In such embodiments, the etch rates thus obtained are still considered as measured under the same conditions even though the etching times may be different (when other conditions are the same).

In some embodiments, the etching compositions of the present disclosure can be substantially free of one or more of additive components, in any combination, if more than one. Such components are selected from the group consisting of organic solvents, polymers (e.g., non-ionic, cationic, or anionic polymers), oxygen scavengers, quaternary ammonium compounds (e.g., salts or hydroxides), alkaline bases (such as NaOH, KOH, LiOH, Mg(OH)₂, and Ca(OH)₂), surfactants (e.g., cationic, anionic, or non-ionic surfactants), defoamers, fluorine-containing compounds (e.g., fluoride compounds or fluorinated compounds (such as fluorinated polymers/surfactants)) other than fluorine-containing inorganic acids or salts thereof, silicon-containing compounds such as silanes (e.g., alkoxysilanes) other than described herein, nitrogen-containing compounds other than described herein (e.g., amino acids, amines, imines (e.g., amidines such as 1,8-diazabicyclo[5.4.0]-7-undecene (DBU) and 1,5-diazabicyclo[4.3.0]non-5-ene (DBN)), amides, or imides), abrasives (e.g., ceria abrasives, non-ionic abrasives, surface modified abrasives, negatively/positively charged abrasive, or ceramic abrasive composites), plasticizers, oxidizing agents (e.g., peroxides such as hydrogen peroxide, and periodic acid), corrosion inhibitors (e.g., azole or non-azole corrosion inhibitors), electrolytes (e.g., polyelectrolytes), silicates, cyclic compounds other than described herein (e.g., azoles (such as diazoles, triazoles, or tetrazoles), triazines, and cyclic compounds containing at least two rings such as substituted or unsubstituted naphthalenes, or substituted or unsubstituted biphenylethers), chelating agents, buffering agents, acids such as organic acids (e.g., carboxylic acids such as hydroxycarboxylic acids, polycarboxylic acids, and sulfonic acid) and inorganic acids (e.g., sulfuric acid, sulfurous acid, nitrous acid, nitric acid, phosphorous acid, and phosphoric acid), salts (e.g., halide salts or metal salts), and catalysts (e.g., metal-containing catalysts). In some embodiments, the composition is substantially free of a salt other than a quaternary ammonium salt. As used herein, a component that is “substantially free” from an etching composition refers to an ingredient that is not intentionally added into the etching composition. In some embodiments, the etching composition described herein can have at most about 1000 ppm (e.g., at most about 500 ppm, at most about 250 ppm, at most about 100 ppm, at most about 50 ppm, at most about 10 ppm, or at most about 1 ppm) of one or more of the above components that are substantially free from the etching composition. In some embodiments, the etching compositions described herein can be completely free of one or more of the above components.

The etching composition of this disclosure can be prepared by simply mixing the components together, or can be prepared by blending two or more compositions (each containing certain components of an etching composition described herein) in a kit.

In some embodiments, the present disclosure features a method of etching a semiconductor substrate that includes a SiN film (e.g., in a SiN-containing feature). The method can include contacting a semiconductor substrate containing the SiN film with an etching composition described herein to substantially remove the SiN film. In some embodiments, the semiconductor substrate can include a pattern or a feature on a surface and the SiN film is a part of the pattern or feature. In some embodiments, the method can further include rinsing the semiconductor substrate with a rinse solvent after the contacting step and/or drying the semiconductor substrate after the rinsing step.

In some embodiments, the contacting step can be performed at an elevated temperature. For example, the contacting step can performed at a temperature ranging from at least about 110° C. (e.g., at least about 115° C., at least about 120° C., at least about 125° C., or at least about 130° C.) to at most about 160° C. (e.g., at most about 155° C., at most about 150° C., at most about 145° C., at most about 140° C., at most about 135° C., or at most about 130° C.). Without wishing to be bound by theory, it is believed that performing the contacting step at an elevated temperature (e.g., in the range described above) can increase the SiN etch rate of the etching composition.

In some embodiments, the method does not substantially remove a metal conductor (e.g., Cu) or a dielectric material other than SiN (e.g., SiOx or SiOCN) in the semiconductor substrate. For example, the method does not remove more than about 5% by weight (e.g., more than about 3% by weight or more than about 1% by weight) of a metal conductor or a dielectric material in the semiconductor substrate.

In some embodiments, the etching method includes the steps of:
(A) providing a semiconductor substrate containing a SiN film (e.g., a SiN film in a pattern or feature);
(B) contacting the semiconductor substrate with an etching composition described herein;
(C) rinsing the semiconductor substrate with one or more suitable rinse solvents; and
(D) optionally, drying the semiconductor substrate (e.g., by any suitable means that removes the rinse solvent and does not compromise the integrity of the semiconductor substrate).

The semiconductor substrates to be etched in this method can contain organic and organometallic residues, and a range of metal oxides, some or all of which may also be removed during the etching process.

Semiconductor substrates described herein (e.g., wafers) typically are constructed of silicon, silicon germanium, Group III-V compounds such as GaAs, or any combination thereof. The semiconductor substrates can additionally contain exposed integrated circuit structures such as interconnect features (e.g., metal lines and dielectric materials). Metals and metal alloys used for interconnect features include, but are not limited to, aluminum, aluminum alloyed with copper, copper, titanium, tantalum, cobalt, silicon, titanium nitride, tantalum nitride, and tungsten. The semiconductor substrates can also contain layers of interlayer dielectrics, polysilicon, silicon oxide, silicon nitride, silicon germanium, silicon carbide, titanium oxide, and carbon doped silicon oxides.

A semiconductor substrate can be contacted with the etching composition by any suitable method, such as placing the etching composition into a tank and immersing and/or submerging the semiconductor substrate into the etching composition, spraying the etching composition onto the semiconductor substrate, streaming the etching composition onto the semiconductor substrate, or any combinations thereof.

The etching composition of the present disclosure can be effectively used up to a temperature of from at least about 110° C. to about 160° C.. The etch rates of SiN increase with temperature in this range, thus the processes at a higher temperature can be run for shorter times. Conversely, lower etching temperatures typically require longer etching times.

Etching times can vary over a wide range depending on the particular etching method, thickness, and temperature employed. When etching in an immersion batch type process, a suitable time range is, for example, up to about 10 minutes (e.g., from about 1 minute to about 7 minutes, from about 1 minute to about 5 minutes, or from about 2 minutes to about 4 minutes). Etching times for a single wafer process can range from about 30 seconds to about 60 minutes (e.g., from about 1 minute to about 60 minutes, from about 10 minutes to about 60 minutes, from about 20 minutes to about 60 minutes, or from about 30 minutes to about 60 minutes).

To further promote the etching ability of the etching composition of the present disclosure, mechanical agitation means can be employed. Examples of suitable agitation means include circulation of the etching composition over the substrate, streaming or spraying the etching composition over the substrate, and ultrasonic or megasonic agitation during the etching process. The orientation of the semiconductor substrate relative to the ground can be at any angle. Horizontal or vertical orientations are preferred.

In some embodiments of the disclosure, to further promote the etching ability of the etching composition of the present disclosure, periodic addition of hydrofluoric acid (HF) to the etching composition is contemplated. This may be referred to as an “HF spike” of the etching composition. Generally, it is desirable for the etching compositions of the disclosure to be capable of etching as many wafers as possible, for as long a time as possible. Over time, as silica dissolves in the etching compositions, etching effectiveness tends to decrease. By adding HF to the etching compositions, effective SiN etching can be maintained. Without wishing to be bound by theory, it is believed that total fluorine and total Si concentrations in the etching compositions during etching should be maintained from 5 to 10 mol/L.

Subsequent to etching, the semiconductor substrate can be rinsed with a suitable rinse solvent for about 5 seconds up to about 5 minutes with or without agitation means. Multiple rinse steps employing different rinse solvents can be employed. Examples of suitable rinse solvents include, but are not limited to, deionized (DI) water, methanol, ethanol, isopropyl alcohol, N-methylpyrrolidinone, gamma-butyrolactone, dimethyl sulfoxide, ethyl lactate, and propylene glycol monomethyl ether acetate. Alternatively, or in addition, aqueous rinses with pH>8 (such as dilute aqueous ammonium hydroxide) can be employed. The rinse solvent can be applied using means similar to that used in applying an etching composition described herein. The etching composition may have been removed from the semiconductor substrate prior to the start of the rinsing step or it may still be in contact with the semiconductor substrate at the start of the rinsing step. In some embodiments, the temperature employed in the rinsing step is between 16° C. and 27° C.

Optionally, the semiconductor substrate is dried after the rinsing step. Any suitable drying means known in the art can be employed. Examples of suitable drying means include spin drying, flowing a dry gas across the semiconductor substrate, or heating the semiconductor substrate with a heating means such as a hotplate or infrared lamp, Maragoni drying, rotagoni drying, IPA drying, and any combinations thereof. Drying times will be dependent on the specific method employed but are typically on the order of 30 seconds up to several minutes.

In some embodiments, the etching method described herein further includes forming a semiconductor device (e.g., an integrated circuit device such as a semiconductor chip) from the semiconductor substrate obtained by the method described above.

While the invention has been described in detail with reference to certain embodiments thereof, it will be understood that modifications and variations are within the spirit and scope of that which is described and claimed.

The present disclosure is illustrated in more detail with reference to the following examples, which are for illustrative purposes and should not be construed as limiting the scope of the present disclosure.

### EXAMPLES

### General Procedure 1

### Formulation Blending

Samples of etching compositions were prepared by adding, while stirring, to the calculated amount of the solvent the remaining components of the formulation.

### General Procedure 2

### Materials and Methods

Blanket film etch rate measurements on films were carried out using commercially available unpatterned 300 mm diameter wafers that were diced into 1.5 cm×5.0 cm test coupons for evaluation. Primary blanket film materials used for testing include 1) a SiN film having a thickness of about 40 Å deposited on a silicon substrate and 2) a SiOCN film having a thickness of about 103 Å deposited on a silicon substrate. The SiN film was not pre-treated before measurement, while the SiOCN film was pretreated with a 1:100 diluted HF aqueous solution for one minute before measurement.

The blanket film test coupons were measured for pre-treatment and post-treatment thickness to determine blanket film etch rates. For the SiN and SiOCN blanket films, the film thicknesses were measured pre-treatment and post-treatment by Ellipsometry using a Woollam VASE at three points for each coupon.

### General Procedure 3

Etching Evaluation with Beaker Test

All blanket film etch testing was carried out in a 500 ml PFA round bottom flask containing 250 g of a sample solution with continuous stirring at 250 rpm. The PFA round bottom flask was placed in a mantle heater and set at a desired temperature. A water cooled condenser was attached to the top of the PFA round bottom flask to return the condensed water to the PFA flask. All blanket test coupons having a blanket film exposed on one side to the sample solution were diced by diamond scribe into 1.5 cm×5.0 cm test coupon size for beaker scale testing. Each individual test coupon was held into position using a single 4″ long, locking plastic tweezers clip. The test coupon, held on one edge by the locking tweezers clip, was suspended into the 500 ml PFA flask and immersed into the 250 g test solution while the solution was stirred continuously at 250 rpm at 130° C. The test coupons were held static in the stirred solution until the treatment time (1 minute or 20 minutes) had elapsed.

After the treatment time had elapsed, the sample coupons were immediately removed from the 500 ml PFA flask and rinsed. Specifically, the coupon was immersed in a 300 mL volume of ultra-high purity deionized (DI) water for 15 seconds with mild agitation, which was followed by immersion in 300 mL of isopropyl alcohol (IPA) for 15 seconds with mild agitation, and a final rinse by immersion in 300 mL of IPA for 15 seconds with mild agitation. After the final IPA rinse step, all test coupons were subject to a filtered nitrogen gas blow off step using a hand held nitrogen gas blower which forcefully removed all traces of IPA to produce a final dry sample for test measurements.

### Example 1

Formulation Example 1 (FE-1) and Comparative Formulation Example 1 (CFE-1) were prepared according to General Procedure 1, and evaluated according to General Procedures 2 and 3. The formulations of FE-1 and CFE-1 are summarized in Table 1. For each of FE-1 and CFE-1, five samples (i.e., S1-S5) were evaluated and their results are summarized in Table 2. In Table 2, the Si/N etch rates were measured after immersing a test coupon in a formulation for 1 minute at 130° C., and the SiOCN etch rates were measured after immersing a test coupon in a formulation for 20 minutes at 130° C.

TABLE 1

| | H₃PO₄ | H₂SiF₆ | TMSPEI | NAETMAS | | |
|---|---|---|---|---|---|---|
| Formulations | (wt %) | (wt %) | (wt %) | (wt %) | Water (wt %) | Total |
| FE-1 | 77% | 0.025% | 0.1% | 0.26% | remainder | 100% |
| CFE-1 | 77% | 0.025% | 0.1% | None | remainder | 100% |

TMSPEI = Trimethoxysilyl polyethyleneimine
NAETMAS = N-(2-aminoethyl)-2,2,4-trimethyl-1-aza-2-silacyclopentane

TABLE 2

| | FE-1 | | | | | CFE-1 | | | | |
|---|---|---|---|---|---|---|---|---|---|---|
| | S1 | S2 | S3 | S4 | S5 | S1 | S2 | S3 | S4 | S5 |
| SiN ER | 37.5 | 38.3 | 36.6 | 36.2 | 34.1 | 41.6 | 34.5 | 29.0 | 22.5 | 17.8 |
| (Å/min) | | | | | | | | | | |
| SiOCN ER | 0.31 | 0.3 | 0.28 | 0.35 | 0.32 | 0.45 | 0.29 | 0.13 | N/A* | N/A* |
| (Å/min) | | | | | | | | | | |
| SiN ER/ | 122.0 | 128.0 | 130.2 | 103.7 | 106.6 | 92.5 | 121.0 | 230.2 | N/A* | N/A* |
| SiOCN ER | | | | | | | | | | |

ER = etch rate
S# = sample number
*SiOCN film thickness increased due to chemical buildup

In general, for an etching composition to be considered having acceptable SiN etch performance, it is desirable for the etching composition to have a SiN etch rate of at least about 30 Å/min, a SiOCN etch rate of at most about 0.3 Å/min, and a SiN/SiOCN etch rate selectivity of at least about 100.

As shown in Table 2, FE-1 (which included a silacyclopentane) generally exhibited SiN etch performance that met the above standards. By contrast, CFE-1 (which did not include a silacyclopentane) did not consistently exhibit SiN etch performance that met the above standards. Without wishing to be bound by theory, it is believed that the silacyclopentane can improve the consistency of the SiN and SiOCN etch rates of the tested etching compositions.

### Example 2

Comparative Formulation Examples 2-5 (CFE-2 to CFE-5) were prepared according to General Procedure 1, and evaluated according to General Procedures 2 and 3. The formulations of CFE-2 to CFE-5 and their test results are summarized in Table 3. In Table 3, the SiN etch rates were measured after immersing a test coupon in a formulation for 1 minute, and the SiOCN etch rates were measured after immersing a test coupon in a formulation for 20 minutes.

TABLE 3

| | | Silicate | | | | Etch | SiN | SiOCN | |
|---|---|---|---|---|---|---|---|---|---|
| | H₃PO₄ | Source | Additive | Water | | Temp | ER | ER | SIN ER/ |
| Formulations | (wt %) | (wt %) | (wt %) | (wt %) | Total | (° C.) | (Å/min | (Å/min) | SiOCN ER |
| CFE-2 | 85% | None | None | remainder | 100% | 150 | 36.7 | 6.1 | 6.0 |
| CFE-3 | 85% | Silicic acid | None | remainder | 100% | 150 | 39.1 | 4.9 | 8.0 |
| | | (50 ppm) | | | | | | | |
| CFE-4 | 85% | (NH₄)₂SiF₆ | None | remainder | 100% | 140 | 45.2 | 5.4 | 8.3 |
| | | (0.1%) | | | | | | | |
| CFE-5 | 85% | H₂SiF₆ | APTES | remainder | 100% | 150 | 38.0 | 2.5 | 15.0 |
| | | (0.01%) | (0.018%) | | | | | | |
| | | | Tartaric | | | | | | |
| | | | acid (1.5%) | | | | | | |

APTES = (3-aminopropyl)triethoxysilane

As shown in Table 3, none of CFE-2 to CFE-5 exhibited SiN etch performance that met the standards set forth in Example 1.

What is claimed is:

1. An etching composition, comprising:
phosphoric acid;
at least one fluorine-containing inorganic acid or a salt thereof;
at least one nitrogen-containing compound comprising an alkoxysilane group;
at least one silane compound different from the at least one nitrogen-containing compound, the at least one silane compound comprising a —Si—N— group, a halo group, an aminoalkyl group, an alkoxyl group, or a combination thereof; and
water.

2. The composition of claim 1, wherein the phosphoric acid is in an amount of from about 60 wt % to about 85 wt % of the etching composition.

3. The composition of claim 1, wherein the at least one fluorine-containing inorganic acid or a salt thereof comprises hexafluorosilicic acid, methylpentafluorosilicic acid, ammonium hexafluorosilicate, hexafluorophosphoric acid, ammonium hexafluorophosphate, tetrafluoroboric acid, hexafluorotitanic acid, or hexafluorozirconic acid.

4. The composition of claim 1, wherein the at least one fluorine-containing inorganic acid or a salt thereof is in an amount of from about 0.001 wt % to about 0.1 wt % of the etching composition.

5. The composition of claim 1, wherein the at least one nitrogen-containing compound comprises an alkoxysilane substituted polyethyleneimine or a salt thereof.

6. The composition of claim 5, wherein the alkoxysilane substituted polyethyleneimine is a monoalkoxysilane substituted polyethyleneimine, a dialkoxysilane substituted polyethyleneimine, or a trialkoxysilane substituted polyethyleneimine.

7. The composition of claim 5, wherein the alkoxysilane substituted polyethyleneimine is a polymer having a monomer repeat unit of formula (I): 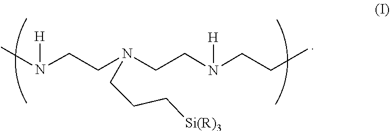
in which each R independently is a C₁-C₆ alkyl or C₁-C₆ alkoxy and at least one R is C₁-C₆ alkoxy.

8. The composition of claim 5, wherein the alkoxysilane substituted polyethyleneimine has an average molecular weight number of from about 500 g/mol to about 5000 g/mol.

9. The composition of claim 1, wherein the at least one nitrogen-containing compound comprises an alkoxysilane substituted trialkylamine compound or an alkoxysilane substituted tetraalkylammonium salt.

10. The composition of claim 9, wherein the alkoxysilane substituted tetraalkylammonium salt is a compound of formula (II): 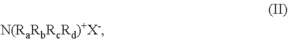
in which
Rₐ is C₁-C₆ alkyl substituted by Si(R′)₃, wherein each R′ independently is a C₁-C₆ alkyl or C₁-C₆ alkoxy and at least one R′ is C₁-C₆ alkoxy;
each of R_{b}, R_{c}, and R_{d} independently is C₁-C₁₅ alkyl; and
X is a halogen.

11. The composition of claim 10, wherein the alkoxysilane substituted tetraalkylammonium salt is

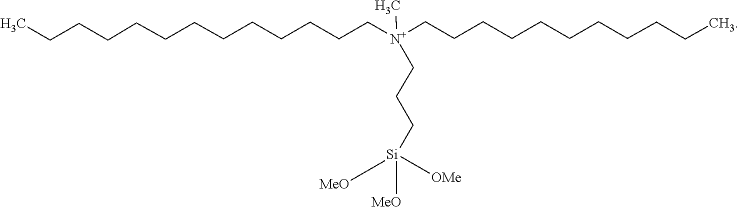 [SMILES: CCCCCCCCCCCCC[N+](C)(CCCCCCCCCCC)CCC[Si](OC)(OC)OC]

12. The composition of claim 1, wherein the at least one nitrogen-containing compound is in an amount of from about 0.001 wt % to about 1 wt % of the etching composition.

13. The composition of claim 1, wherein the at least one silane compound comprises an azasilacyclopentane compound, an azasilane compound, or a trialkylsilane compound optionally comprising at least one substituent that comprises a nitrogen atom, an oxygen atom, or a halogen atom.

14. The composition of claim 13, wherein the azasilacyclopentane compound is a compound of formula (III): 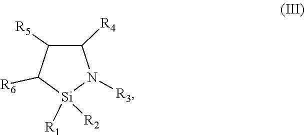
in which each of R₁-R₆, independently, is H or C₁-C₆ alkyl optionally substituted by NH₂.

15. The composition of claim 14, wherein R₃ is CH₃ or (CH₂)(CH₂)NH₂.

16. The composition of claim 14, wherein the compound of formula (III) is

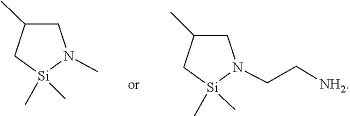

17. The composition of claim 1, wherein the at least one silane compound comprises

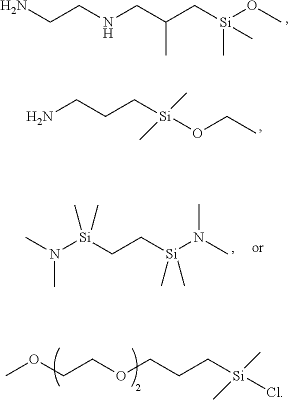

18. The composition of claim 1, wherein the at least one silane compound is in an amount of from about 0.01 wt % to about 5 wt % of the etching composition.

19. The composition of claim 1, wherein the water is in an amount of from about 15 wt % to about 40 wt % of the etching composition.

20. The composition of claim 1, wherein the composition has a pH of from about 0 to about 2.

21. The composition of claim 1, wherein the composition has a SiN/SiOCN etch rate selectivity of at least about 100 when the etch rates of SiN and SiOCN are measured under the same conditions.

22. The composition of claim 1, wherein the composition has a SiN/SiOx etch rate selectivity of at least about 10 when the etch rates of SiN and SiOx are measured under the same conditions.

23. A method, comprising:
contacting a semiconductor substrate containing a SiN film with the composition of claim 1 to substantially remove the SiN film.

24. The method of claim 23, wherein the method does not substantially remove silicon oxide or silicon oxycarbonitride.

25. The method of claim 23, wherein the contacting step is performed at a temperature from 110° C. to about 160° C.

26. An article formed by the method of claim 23, wherein the article is a semiconductor device.

27. The article of claim 26, wherein the semiconductor device is an integrated circuit.
